(19) United States
(12) Patent Application Publication
(10) Pub. No.: US 2026/0188981 A1
(43) Pub. Date: Jul. 2, 2026

(54) SEMICONDUCTOR LIGHT EMITTING ELEMENT

(71) Applicant: NICHIA CORPORATION, Anan-shi (JP)

(72) Inventor: Katsuhiro KISHIMOTO, Anan-shi (JP)

(21) Appl. No.: 19/432,903

(22) Filed: Dec. 24, 2025

(30) Foreign Application Priority Data
Dec. 27, 2024 (JP) 2024-231977

(51) Int. Cl. H01S 5/343

(52) U.S. Cl. CPC H01S 5/34333

(57) ABSTRACT

A semiconductor light emitting element includes a GaN substrate; a first nitride semiconductor portion containing an n-type impurity and located on the substrate; a second nitride semiconductor portion containing an n-type impurity and located on the first nitride semiconductor portion; and a third nitride semiconductor portion containing an n-type impurity and located on the second nitride semiconductor portion. An n-type impurity concentration of the first nitride semiconductor portion is higher than that of the third nitride semiconductor portion, and an n-type impurity concentration of the second nitride semiconductor portion is higher than that of the third nitride semiconductor portion. An Al composition ratio of the second nitride semiconductor portion is higher than that of the first nitride semiconductor portion, and an Al composition ratio of the third nitride semiconductor portion is higher than that of the first nitride semiconductor portion.

### CROSS-REFERENCE TO RELATED APPLICATION

This application claims priority to Japanese Patent Application No. 2024-231977 filed on Dec. 27, 2024, the disclosure of which is hereby incorporated herein by reference in its entirety.

### BACKGROUND

### Technical Field

The present disclosure relates to a semiconductor light emitting element.

### Background Art

A technique for growing an n-type semiconductor layer on a GaN substrate for use as a blue light emitting semiconductor element has been known. See, for example, Japanese Patent Publication No. 2006-093683.

### SUMMARY

Some GaN substrates have poor flatness. When an n-type semiconductor layer is grown on such a GaN substrate, the poor flatness may be inherited to an n-type semiconductor layer grown on the substrate. This may result in generation of ripples in a far field pattern (hereinafter referred to as “FFP”) of the light emitted by the resultant semiconductor light emitting element.

One object of the present disclosure is to provide a semiconductor light emitting element that exhibits FFP in which ripples are reduced.

A semiconductor light emitting element according to one embodiment of the present disclosure includes a GaN substrate; a first nitride semiconductor portion containing an n-type impurity and located on the substrate; a second nitride semiconductor portion containing an n-type impurity and located on the first nitride semiconductor portion; and a third nitride semiconductor portion containing an n-type impurity and located on the second nitride semiconductor portion. An n-type impurity concentration of the first nitride semiconductor portion is higher than an n-type impurity concentration of the third nitride semiconductor portion, and an n-type impurity concentration of the second nitride semiconductor portion is higher than the n-type impurity concentration of the third nitride semiconductor portion. An Al composition ratio of the second nitride semiconductor portion is higher than an Al composition ratio of the first nitride semiconductor portion, and an Al composition ratio of the third nitride semiconductor portion is higher than the Al composition ratio of the first nitride semiconductor portion.

According to an embodiment of the present disclosure, a semiconductor light emitting element that exhibits FFP in which ripples are reduced can be provided.

### BRIEF DESCRIPTION OF THE DRAWINGS

FIG. 1 is a schematic cross-sectional view of a semiconductor light emitting element according to an embodiment.

FIG. 2 is a schematic cross-sectional view of the n-side semiconductor layer 2 in the embodiment.

FIG. 3 is a graph showing the SIMS results in the depth direction from the n-side semiconductor layer to the substrate of the semiconductor light emitting element in an example.

FIG. 4 is a graph showing the FFPs in the example and a comparative example.

### DETAILED DESCRIPTION

Semiconductor light emitting elements according to certain embodiments of the present invention will be explained below with reference to the accompanying drawings. In the description below, terms indicating specific directions or positions (e.g., “upper,” “lower,” and other terms including or related to these) may be used as needed. These terms, however, are merely used in order to facilitate understanding of the relative directions or positions in the drawings being referenced, and are not intended to limit the technical scope of the present invention. The same reference numerals appearing in multiple drawings denote the same or similar parts or members. The embodiments described below are exemplary light emitting devices provided to give a concrete form to the technical ideas of the present invention, and are not intended to limit the present invention to those described below. The dimensions, the shapes, and the relative positions of and the materials for the constituent elements described below are not intended to limit the scope of the present invention unless otherwise specifically stated, and are intended for illustration purposes. The description provided in one embodiment is applicable to other embodiments or variations. The sizes of and relative positions of the members shown in the drawings might be exaggerated for clarity of explanation. In order to avoid making a drawing excessively complex, a schematic view in which certain elements are omitted might be used, or an end view showing only a cut section might be used as a cross-sectional view. In the present specification, the direction from the n-side semiconductor layer to the p-side semiconductor layer may be referred to as “upper” or “upward”, and a direction opposite thereto may be referred to as “lower” or “downward”.

### Embodiment 1

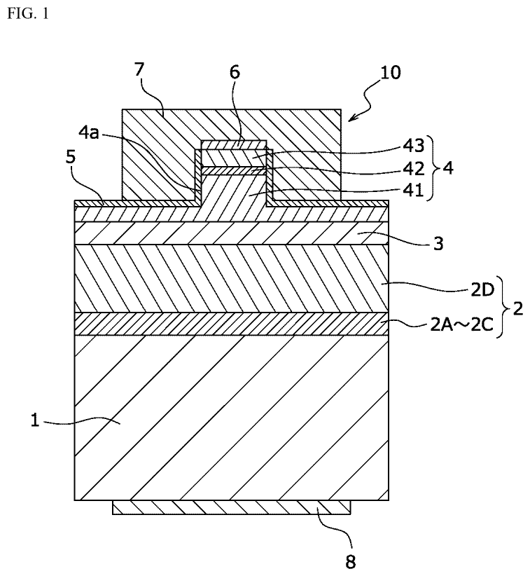

A semiconductor light emitting element according to Embodiment 1 includes, as shown in FIG. 1, a substrate 1, and an n-side semiconductor layer 2, an active layer 3, and a p-side semiconductor layer 4 provided on the substrate 1 in this order. Each of the n-side semiconductor layer 2, the active layer 3, and the p-side semiconductor layer 4 is made of a nitride semiconductor. Among these layers, the n-side semiconductor layer 2 includes a first nitride semiconductor portion 2A disposed on the substrate 1, a second nitride semiconductor portion 2B disposed on the first nitride semiconductor portion 2A, a third nitride semiconductor portion 2C disposed on the second nitride semiconductor portion 2B, and an n-type semiconductor layer 2D containing an n-type impurity disposed on the third nitride semiconductor portion 2C. In the example herein, the semiconductor light emitting element is, for example, a semiconductor laser element.

### Substrate 1

For a substrate 1, a nitride semiconductor substrate made of GaN or the like, for example, is used. A principal surface of the substrate 1 is, for example, +c-plane ((0001) plane). The principal surface of the substrate 1 can have an off-angle of up to ±1 degree. Employing a substrate having +c-plane as a principal surface can increase mass producibility. The thickness of the substrate 1 is, for example, 400 μm to 500 μm.

The substrate 1 contains, for example, Ge. The Ge concentration in this case can be, for example, 1×10¹⁸ cm⁻³ to 5×10¹⁸ cm⁻³.

### N-Side Semiconductor Layer 2

An n-side semiconductor layer 2 includes, in one portion thereof, a first nitride semiconductor portion 2A, a second nitride semiconductor portion 2B, and a third nitride semiconductor portion 2C disposed on the substrate 1. These portions are preferably arranged such that the substrate 1 is in contact with the first nitride semiconductor portion 2A, the first nitride semiconductor portion 2A is in contact with the second nitride semiconductor portion 2B, and the second nitride semiconductor portion 2B is in contact with the third nitride semiconductor portion 2C. This configuration allows for reducing the thickness of the n-side semiconductor layer 2.

Each of the first nitride semiconductor portion 2A, the second nitride semiconductor portion 2B, and the third nitride semiconductor portion 2C contains an n-type impurity. Examples of n-type impurities include Si and Ge. The first nitride semiconductor portion 2A may or may not include Al as a component. The second nitride semiconductor portion 2B and the third nitride semiconductor portion 2C contain Al as a component. The second nitride semiconductor portion 2B and the third nitride semiconductor portion 2C are, for example, AlGaN. The Al composition ratio of the second nitride semiconductor portion 2B is higher than the Al composition ratio of the first nitride semiconductor portion 2A, and the Al composition ratio of the third nitride semiconductor portion 2C is higher than the Al composition ratio of the first nitride semiconductor portion 2A. The Al composition ratio of the second nitride semiconductor portion 2B is preferably the same as the Al composition ratio of the third nitride semiconductor portion 2C. Accordingly, the lattice constant of the second nitride semiconductor portion 2B can be close to that of the third nitride semiconductor portion 2C.

The third nitride semiconductor portion 2C is required to have a high degree of crystallinity because it serves as the base structure for the n-type semiconductor layer 2D, the active layer 3, and the p-side semiconductor layer 4. Accordingly, the third nitride semiconductor portion 2C is desired to be grown in the state in which the substrate 1 is maintained at a high temperature. However, a surface of the substrate may become asperous as a result of thermal desorption when the substrate 1 is heated. The surface asperities do not disappear even after the growth of the layers, and are reflected in the layers stacked on the substrate 1. This may lead to reduction in the optical confinement performance, allowing the light emitted by the active layer 3 to leak to the substrate 1. The leaked rays of light reinforce one another at a distance, causing ripples to occur in an FFP. Accordingly, with the first nitride semiconductor portion 2A and the second nitride semiconductor portion 2B having high n-type impurity concentrations provided between the substrate 1 and the third nitride semiconductor portion 2C, the planar diffusion of atoms during the growth of nitride semiconductors can be increased, thereby reducing surface asperities. This allows for reducing ripples occurring in an FFP of the light from the semiconductor light emitting element.

Furthermore, the n-type impurity concentration of the first nitride semiconductor portion 2A is higher than the n-type impurity concentration of the third nitride semiconductor portion 2C. The n-type impurity concentration of the second nitride semiconductor portion 2B is higher than the n-type impurity concentration of the third nitride semiconductor portion 2C. An n-type impurity contained in a nitride semiconductor can increase the planar diffusion of atoms during the growth, thereby reducing asperities of the surface. This allows the first nitride semiconductor portion 2A and the second nitride semiconductor portion 2B to have higher flatness. Moreover, because the Al composition ratio differs between the first nitride semiconductor portion 2A and the second nitride semiconductor portion 2B, the interface of these nitride semiconductors tends to be asperous. Adding an n-type impurity to the first nitride semiconductor portion 2A and the second nitride semiconductor portion 2B can reduce such asperities at the interface thereof. This, as a result, allows for reducing ripples in an FFP of the light from the semiconductor light emitting element. The n-type impurity concentration of the first nitride semiconductor portion 2A can be, for example, equal to or higher than 10 times the n-type impurity concentration of the third nitride semiconductor portion 2C, and equal to or less than 50 times the n-type impurity concentration of the third nitride semiconductor portion 2C. The n-type impurity concentration of the second nitride semiconductor portion 2B can be, for example, equal to or higher than 10 times the n-type impurity concentration of the third nitride semiconductor portion 2C. Specifically, the n-type impurity concentration of the first nitride semiconductor portion 2A can be 5×10¹⁹ cm⁻³ or higher, and can be 5×10²⁰ cm⁻³ or less. The n-type impurity concentration of the second nitride semiconductor portion 2B can be 5×10¹⁹ cm⁻³ or higher, and can be 5×10²⁰ cm⁻³ or less. Setting the n-type concentrations to fall within these numerical value ranges allows the semiconductor light emitting element to have suitable conductivity. In the example described later, the n-type impurity concentration of the second nitride semiconductor portion 2B is higher than the n-type impurity concentration of the first nitride semiconductor portion 2A. With such concentrations, the n-type impurity allows for reducing the difficulty in atom diffusion in an in-plane direction due to Al contained in the second nitride semiconductor portion 2B during the growth, thereby reducing asperities of the surface. Accordingly, ripples in an FFP of the light from the semiconductor light emitting element can be reduced.

The thickness of the first nitride semiconductor portion 2A can be in a range of 2 nm to 10 nm, for example. The thickness of the second nitride semiconductor portion 2B can be in a range of 2 nm to 10 nm, for example. The thickness of the third nitride semiconductor portion 2C can be in a range of 1000 nm to 1500 nm, for example. Particularly, the sum of the thicknesses of the first nitride semiconductor portion 2A and the second nitride semiconductor portion 2B may be larger or smaller than, or the same as the thickness of the GaN substrate 1 and the thickness of the third nitride semiconductor portion 2C, but is preferably smaller than that. The sum of the thicknesses of the first nitride semiconductor portion 2A and the second nitride semiconductor portion 2B is preferably in a range of 5 nm to 30 nm. Setting the value in this range allows for greatly reducing the optical loss of the semiconductor light emitting element attributed to impurities while achieving the ripple reduction effect.

On the third nitride semiconductor portion 2C, an n-type semiconductor layer 2D is disposed, which is a component of the n-side semiconductor layer 2 besides the first nitride semiconductor portion 2A, the second nitride semiconductor portion 2B, and the third nitride semiconductor portion 2C. The n-type semiconductor layer 2D disposed on the third nitride semiconductor portion 2C can be one or more layers made of a nitride semiconductor, such as GaN, InGaN, AlGaN or the like.

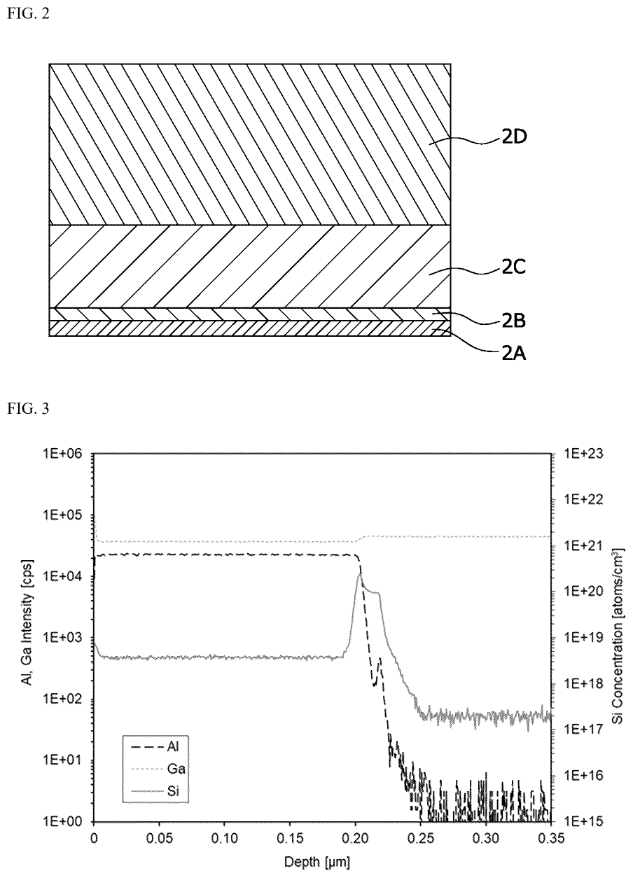

The n-side semiconductor layer 2 has a stack structure such as that shown in FIG. 2. In other words, the n-side semiconductor layer 2 includes, in order from the substrate 1 side, the first nitride semiconductor portion 2A and the second nitride semiconductor portion 2B, and further includes the third nitride semiconductor portion 2C as an underlayer on the second nitride semiconductor portion 2B. The n-type semiconductor layer 2D is disposed on the third nitride semiconductor portion 2C. The n-type semiconductor layer 2D includes, for example, a first n-side clad layer, a crack inhibiting layer, an intermediate layer, a second n-side clad layer, a first n-side light guide layer, a second n-side light guide layer, and a hole blocking layer. The hole blocking layer has a first hole blocking layer and a second hole blocking layer. In other words, a crack inhibiting layer is included between the third nitride semiconductor portion 2C and one of the layers making up the n-type semiconductor layer 2D. The first n-side clad layer has a larger band gap energy than that of the n-side light guide layers. Because an n-type impurity can also cause optical absorption even though not as much as a p-type impurity, the n-side light guide layers are preferably undoped, or have a lower n-type impurity concentration than that of the first n-side clad layer.

The n-type semiconductor layer 2D composed of these nitride semiconductors include semiconductor layers each containing one or more n-type impurities. Examples of n-type impurities include, Si, Ge, and the like. For example, the layers from the first n-side clad layer to the first n-side light guide layer are doped with an n-type impurity. The first n-side clad layer has a larger band gap energy than that of the third nitride semiconductor portion 2C, and is a layer doped with an n-type impurity. The crack inhibiting layer is InGaN, for example, and has a smaller band gap energy than that of the well layers in the active layer 3. Providing a crack inhibiting layer can reduce the probability of crack formation. The intermediate layer has a lattice constant that is between those of the crack inhibiting layer and the second n-side clad layer, and is made of GaN, for example. In the case in which the crack inhibiting layer is an InGaN layer, a GaN intermediate layer is preferably formed before growing the second n-side clad layer. If a second n-side clad layer is grown in contact with the upper surface of the crack inhibiting layer, a portion of the crack inhibiting layer could break down to affect even the growth of the active layer 3. Providing an intermediate layer can reduce the probability of such degradation. The intermediate layer is preferably formed to a smaller thickness than that of the crack inhibiting layer, for example. The second n-side clad layer is a layer having larger band gap energy than the third nitride semiconductor portion 2C, for example, and may be the same as the first n-side clad layer. The first n-side clad layer and the second n-side clad layer are, for example, AlGaN. One or both of the first n-side clad layer and the second n-side clad layer may have the largest band gap energy in the n-side semiconductor layer 2. The compositions and/or the n-type impurity concentrations of the first n-side clad layer may be the same as that of the second n-side clad layer. The n-side clad layer may be a single layer, and in this case, a crack inhibiting layer is not provided, or may be provided on or under the n-side clad layer. The first n-side light guide layer has a smaller band gap energy and a lower n-type impurity concentration than those of the first n-side clad layer and the second n-side clad layer. The first n-side light guide layer is, for example, GaN. The band gap energy of the second n-side light guide layer is larger than that of the well layers in the active layer 3, and smaller than that of the first n-side light guide layer. Because the second n-side light guide layer is located closer to the active layer 3 than the first n-side light guide layer is, it preferably has a lower n-type impurity concentration than the first n-side light guide layer from the standpoint of reducing optical absorption loss. The second n-side light guide layer is undoped InGaN, for example.

The second n-side light guide layer may be a composition gradient layer in which the band gap energy becomes smaller as the distance to the active layer 3 decreases. In the case of disposing a composition gradient layer as a n-side light guide layer, the composition of the layer is changed in phases such that the refractive index increases as the distance to the active layer 3 decreases. This can continuously form an optical waveguide barrier in the n-side composition gradient layer thereby enhancing the optical confinement of the active layer 3. For the criteria for determining the magnitude relation between the composition gradient layer's band gap energy and impurity concentration and those of the other layers, the average values of the composition gradient layer can be used. An average value of the composition gradient layer refers to that obtained by dividing the sum of the products of individual sublayers'band gap energy or the like and the film thickness by the total film thickness.

A hole blocking layer preferably contains an n-type impurity at least in one portion thereof. This allows the layer to more efficiently block holes. For example, the first hole blocking layer is GaN, and the second hole blocking layer is InGaN.

### Active Layer 3

An active layer 3 can be a multilayer structure made of nitride semiconductors, such as GaN, InGaN, and the like. The active layer 3 has a single or multiple quantum well structure. A multiple quantum well structure is considered to more readily achieve adequate gain than a single quantum well structure. In the case in which the active layer 3 is a multiple quantum well structure, it includes multiple well layers and an intermediate barrier layer interposed between well layers. For example, the active layer 3 includes, successively from the n-side semiconductor layer 2 side, a well layer, an intermediate barrier layer, and a well layer. An n-side barrier layer may be disposed between the n-side semiconductor layer 2 and the well layer closest to the n-side semiconductor layer 2. The n-side barrier layer may function as a part of the hole blocking layer. The hole blocking layer and the n-side light guide layer (the second n-side light guide layer) may be allowed to function as a barrier layer without disposing an n-side barrier layer. Similarly, a p-side barrier layer may be disposed between the p-side semiconductor layer 4 and the well layer closest to the p-side semiconductor layer 4. In the case in which a p-side barrier layer is not provided or provided to have a small thickness, a portion of the p-side semiconductor layer 4 may function as a barrier layer. In the case of disposing a p-side barrier layer in the active layer 3, the thickness of the p-side barrier layer can be 5 nm or less, for example. In other words, the shortest distance between the p-side semiconductor layer 4 and a well layer in the active layer 3 is set to be 5 nm or less, for example. As described above, moreover, doping with a p-type impurity would increase optical absorption loss. Accordingly, the active layer 3 is preferably formed without doping with a p-type impurity. Each layer in the active layer 3 is an undoped layer, for example.

When a semiconductor light emitting element is a semiconductor laser element having an emission wavelength of 530 nm or more, the In composition ratio x of the InₓGa₁₋ₓN well layers is, for example, 0.25 or higher, although it might slightly vary depending on the layering structure of those other than the active layer 3. The upper limit of the In composition ratio x of the well layers is, for example, 0.50 or less. In this case, the emission wavelength of the semiconductor laser element is believed to be about 600 nm or lower.

### P-Side Semiconductor Layer 4

A p-side semiconductor layer 4 can be a multilayer structure made of nitride semiconductors, such as GaN, InGaN, AlGaN, and the like. The p-side semiconductor layer 4 can have a p-side clad layer and a p-side light guide layer, and may include an additional layer. In the case of providing a light transmissive conductive film as a p-electrode 6 on the p-side semiconductor layer 4, the film can function as a clad layer. Thus, a clad layer does not have to be included in the p-side semiconductor layer 4.

The p-side semiconductor layer 4 includes one or more p-type semiconductor layers. Examples of p-type semiconductor layers include nitride semiconductor layers containing a p-type impurity, such as Mg or the like.

The p-side semiconductor layer 4 includes, for example, an undoped or low-concentration doped layer 41, an electron barrier layer 42, and a doped layer 43.

The undoped or low-concentration doped layer 41 is preferably a portion that does not include a p-type semiconductor layer. The thickness of the undoped or low-concentration doped layer 41 is preferably 400 nm or larger. The upper limit value of the thickness of the undoped or low-concentration doped layer 41 can be set to 660 nm. The undoped or low-concentration doped layer 41 can reduce the probability of electron overflow attributed to the band gap difference from the electron barrier layer 42. For this purpose, the undoped or low-concentration doped layer 41 preferably has, as the layer that is in contact with the electron barrier layer 42, a layer having smaller band gap energy than the electron barrier layer 42.

In the case in which the undoped or low-concentration doped layer 41 is a low-concentration doped layer, the p-type impurity concentration is preferably set to be lower than the p-type impurity concentration of the electron barrier layer 42 across the entire layer. The n-type impurity concentration of the low-concentration doped layer can be lower than 2×10¹⁸/cm³, for example, and the layer preferably does not substantially contain any n-type impurity.

In the case in which the undoped or low-concentration doped layer 41 is a low-concentration doped layer, the low-concentration doped layer 41 may include a p-side composition gradient layer and a p-side intermediate layer. Including a p-side composition gradient layer can enhance the optical confinement of the active layer 3. This, as a result, can reduce the threshold current density for the laser emission. The p-side composition gradient layer is a layer in which the band gap energy increases towards the top. The p-side intermediate layer may be a single layer structure of a single composition or a multilayer structure.

The electron barrier layer 42 contains a p-type impurity such as Mg or the like. The band gap energy of the electron barrier layer 42 is preferably larger than the band gap energy of the undoped or low-concentration doped layer 41. The electron barrier layer 42 having large band gap energy can function as a barrier for overflown electrons from the active layer 3.

The doped layer 43 has one or more p-type semiconductor layers containing a p-type impurity. The p-type impurity concentration of a p-type semiconductor layer in the doped layer 43 is, for example, 1×10¹⁸/cm³ or higher.

A ridge 4a projecting upwards is provided on the p-side semiconductor layer 4. The lower end of the ridge 4a is preferably positioned in the undoped or low-concentration doped layer 41. As described above, an n-type semiconductor layer 2D, an active layer 3, and a p-side semiconductor layer 4 are stacked on the third nitride semiconductor portion 2C. The third nitride semiconductor portion 2C having high flatness can also improve the flatness of the n-type semiconductor layer 2D, the active layer 3, and the p-side semiconductor layer 4 stacked thereon.

### Insulation Film 5, N-Electrode 8, P-Electrode 6, and P-Side Pad Electrode 7

An insulation film 5 can be a single layer or multilayer film of an oxide or nitride of Si, Al, Zr, Ti, Nb, Ta, or the like, for example.

An n-electrode 8 is provided substantially across the entire lower surface of the n-type substrate 1, for example.

A p-electrode 6 is disposed on the upper surface of the ridge 4a. In the case in which the width of the p-electrode 6 is narrow, a p-side pad electrode 7 larger in width than the p-electrode 6 can be provided on the p-electrode 6 to allow a wire to be connected to the p-side pad electrode 7. Examples of materials for each electrode include a single layer or multilayer film of a conductive oxide or the like that contains at least one selected from metals or alloys of Ni, Rh, Cr, Au, W, Pt, Ti, and Al, Zn, In, and Sn. Examples of conductive oxides include ITO (indium tin oxide), IZO (indium zinc oxide), GZO (gallium-doped zinc oxide), and the like. The thickness of each electrode has only to be one that allows it to usually function as an electrode of a semiconductor light emitting element, for example, about 0.1 μm to 2 μm. The p-electrode 6 is preferably a light transmissive conductive film having a smaller refractive index than the refractive index of the active layer 3. This allows the p-electrode to function as a clad layer. Furthermore, the p-electrode 6 is preferably a light transmissive conductive film having a smaller refractive index than the refractive index of the doped layer 43. This can further enhance the optical confinement effect.

### EXAMPLE

As an example, a semiconductor light emitting element 10 shown in FIG. 1 was prepared by growing an n-side semiconductor layer 2, an active layer 3, and a p-side semiconductor layer 4 on a 400 μm thick n-type GaN substrate 1 having +c plane as the upper surface.

A MOCVD system was used to prepare the epitaxial wafer for the semiconductor light emitting element 10. For the raw materials, trimethylgallium (TMG), triethylgallium (TEG), trimethylaluminum (TMA), trimethylindium (TMI), ammonia (NH₃), silane gas, and bis(cyclopentadienyl)magnesium (CP₂Mg) were used.

First, on the GaN substrate 1, as a part of the n-side semiconductor layer 2, a Si-doped 30 nm thick GaN layer and a Si-doped 1.25 μm thick Al_{0.018}Ga_{0.982}N layer were formed. The first nitride semiconductor portion 2A, the second nitride semiconductor portion 2B, and the third nitride semiconductor portion 2C are included in this portion.

In this example, the Ge concentration of the GaN substrate 1 was set to 3×10¹⁸/cm⁻³. The Si concentration of the first nitride semiconductor portion 2A was set to 1×10²⁰/cm⁻³. The Si concentration of the second nitride semiconductor portion 2B was set to 2.5×10²⁰/cm⁻³. The Si concentration of the third nitride semiconductor portion 2C was set to 4×10¹⁸/cm⁻³.

This was followed by successively growing on the third nitride semiconductor portion 2C, as an n-type semiconductor layer 2D, a Si-doped 250 nm thick Al_{0.08}Ga_{0.92}N layer (the first n-side clad layer), a Si-doped 150 nm thick In_{0.04}Ga_{0.96}N layer (the crack inhibiting layer), a Si-doped 10 nm thick GaN layer (the intermediate layer), a Si-doped 650 nm thick Al_{0.08}Ga_{0.92}N layer (the second n-side clad layer), a Si-doped 200 nm thick GaN layer (the first n-side light guide layer), a Si-doped 230 nm thick composition gradient layer (the second n-side light guide layer), a Si-doped 1.2 nm thick GaN layer (the first hole blocking layer), and a Si-doped 44 nm thick In_{0.045}Ga_{0.955}N layer (the second hole blocking layer). The second n-side light guide layer was grown while monotonously increasing the In composition ratio in 120 steps such that the compositional grading is substantially linear starting with GaN and ending with In_{0.045}Ga_{0.955}N.

Then an active layer 3 was grown to successively include a Si-doped GaN layer (the n-side barrier layer), an undoped In_{0.25}Ga_{0.75}N layer (a well layer), an undoped GaN layer (the intermediate barrier layer), an undoped In_{0.25}Ga_{0.75}N layer (a well layer), and an undoped GaN layer (the p-side barrier layer).

This was followed by successively growing as the p-side semiconductor layer 4, an undoped 180 nm thick first composition gradient layer, an undoped 150 nm thick second composition gradient layer, an undoped 200 nm thick AlGaN layer, a Mg-doped 3.9 nm thick Al_{0.10}Ga_{0.90}N layer, a Mg-doped 7 nm thick third composition gradient layer, a Mg-doped 100 nm thick Al_{0.04}Ga_{0.96}N layer, and a Mg-doped 16 nm thick GaN layer. The first composition gradient layer was grown while monotonously decreasing the In composition ratio in 120 steps such that the compositional grading is substantially linear starting with In_{0.045}Ga_{0.955}N and ending with GaN. The second composition gradient layer was grown while monotonously increasing the Al composition ratio in 80 steps such that the compositional grading is substantially linear starting with GaN and ending with Al_{0.04}Ga_{0.96}N. The third composition gradient layer was grown while monotonously decreasing the Al composition ratio in 10 steps such that the compositional grading is substantially linear starting with Al_{0.24}Ga_{0.76}N and ending with Al_{0.17}Ga_{0.83}N.

The epitaxial wafer having the layers described above was removed from the MOCVD system, and a ridge 4a, an insulation film 5, a p-electrode 6, a p-side pad electrode 7, and an n-electrode 8 were formed. The depth of the ridge 4a was set to about 270 nm. For the p-electrode 6, a 200 nm thick ITO film was formed. After the wafer was divided into bars, a reflecting film was formed on the light emission surface and the light reflecting surface. The bars were subsequently divided into individual semiconductor light emitting elements 10.

A sample in which the layers up to the middle of the third nitride semiconductor portion 2C were grown on a substrate 1 in a similar manner to in the semiconductor light emitting element 10 was subjected to secondary-ion mass spectroscopy to obtain the SIMS results in the depth direction from the uppermost surface to the substrate 1.

The profile shown in FIG. 3 was obtained as a result. The profile in FIG. 3 shows, from left to right, the third nitride semiconductor portion 2C, the second nitride semiconductor portion 2B, the first nitride semiconductor portion 2A, and the substrate 1. The leftmost region represents the Al_{0.018}Ga_{0.982}N third nitride semiconductor portion 2C with an Si concentration of about 4×10¹⁸/cm⁻³. The region on the right side of the third nitride semiconductor portion 2C represents the second nitride semiconductor portion 2B having a Si concentration of about 2.5×10²⁰/cm⁻³ and an Al composition ratio of about 1.8%, which is a high Si concentration Al_{0.018}Ga_{0.982}N portion. The region on the right side of the second nitride semiconductor portion 2B represents the first nitride semiconductor portion 2A having a Si concentration of about 1×10²⁰/cm⁻³ and a lower Al composition ratio than that of the second nitride semiconductor portion 2B, which is a high Si concentration GaN portion. The region in which both the Al composition ratio and Si concentration are constantly lower than the first half region represents the substrate 1. In the profile shown in FIG. 3, the Si concentrations are measured values, but the Al and Ga represent relative Al composition ratio based on the detected Al and Ga intensities. In the Al intensities, there is a spike at the depth of 0.22 μm. This is considered to be an error as no Al localization was found in the STEM analysis conducted.

### COMPARATIVE EXAMPLE

A semiconductor light emitting element was prepared as a comparative example. The comparative semiconductor light emitting element was prepared in a similar manner as the semiconductor light emitting element 10 in the example, except for directly forming a Si-doped 1.25 μm thick Al_{0.018}Ga_{0.982}N layer on a GaN substrate without forming, as parts of the n-side semiconductor layer, a Si-doped 3 nm thick GaN layer and a Si-doped 3 nm thick Al_{0.018}Ga_{0.982}N layer.

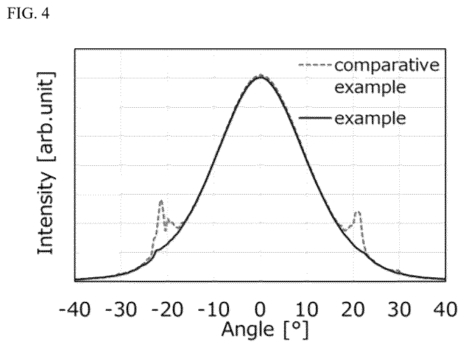

The peak wavelength of the laser light emitted by the resultant semiconductor light emitting element 10 was about 525 nm. A number of semiconductor light emitting elements in the example and the comparative example were produced and the presence of ripples were measured. The ripple occurrence probability was lower for the samples of the example. As shown in FIG. 4, ripples occurred with high probability in the comparative samples as opposed to the example samples in which ripples were scarce. The reasons for this are thought to be as follows.

In a semiconductor light emitting element such as the comparative example, in a portion where the Al composition ratio changes, the semiconductor layer growth mode tends to become unstable due to difference in an in-plane lattice constant, which may induce surface asperities. Accordingly, ripples might easily occur depending on the substrate, and the production yield of semiconductor light emitting elements might be reduced.

In contrast, in a semiconductor light emitting element 10 of the example, high n-type impurity concentration portions, such as the first nitride semiconductor portion 2A and the second nitride semiconductor portion 2B, are disposed on the GaN substrate 1, and the third nitride semiconductor portion 2C is disposed on the second nitride semiconductor portion 2B. In other words, the second nitride semiconductor portion 2B containing high concentration n-type impurity is disposed between the first nitride semiconductor portion 2A containing an n-type impurity at a high concentration (portion having a relatively high Al composition ratio) and the third nitride semiconductor portion 2C containing an n-type impurity at a low concentration (portion having a relatively low Al composition ratio). With a high n-type impurity concentration semiconductor portion located at a portion where the Al composition ratio changes, the semiconductor layer growth can be more two-dimensional at the portion where the Al composition ratio changes, allowing for reducing surface asperities. This can achieve a high flatness semiconductor stack structure, thereby forming a semiconductor light emitting element with high flatness. This can consequently reduce ripples in an FFP of the light from the semiconductor light emitting element.

What is claimed is:

1. A semiconductor light emitting element comprising:
a GaN substrate;
a first nitride semiconductor portion containing an n-type impurity and located on the substrate;
a second nitride semiconductor portion containing an n-type impurity and located on the first nitride semiconductor portion; and
a third nitride semiconductor portion containing an n-type impurity and located on the second nitride semiconductor portion, wherein
an n-type impurity concentration of the first nitride semiconductor portion is higher than an n-type impurity concentration of the third nitride semiconductor portion, and an n-type impurity concentration of the second nitride semiconductor portion is higher than the n-type impurity concentration of the third nitride semiconductor portion, and
an Al composition ratio of the second nitride semiconductor portion is higher than an Al composition ratio of the first nitride semiconductor portion, and an Al composition ratio of the third nitride semiconductor portion is higher than the Al composition ratio of the first nitride semiconductor portion.

2. The semiconductor light emitting element according to claim 1, wherein the n-type impurity concentration of the first nitride semiconductor portion is equal to or higher than 5×10¹⁹ cm⁻³.

3. The semiconductor light emitting element according to claim 1, wherein the n-type impurity concentration of the second nitride semiconductor portion is equal to or higher than 5×10¹⁹ cm⁻³.

4. The semiconductor light emitting element according to claim 1, wherein the n-type impurity concentration of the first nitride semiconductor portion is equal to or higher than 10 times the n-type impurity concentration of the third nitride semiconductor portion.

5. The semiconductor light emitting element according to claim 1, wherein the n-type impurity concentration of the second nitride semiconductor portion is equal to or higher than 10 times the n-type impurity concentration of the third nitride semiconductor portion.

6. The semiconductor light emitting element according to claim 1, wherein a sum of a thickness of the first nitride semiconductor portion and a thickness of the second nitride semiconductor portion is in a range of 5 nm to 30 nm.

7. The semiconductor light emitting element according to claim 1, wherein a sum of a thickness of the first nitride semiconductor portion and a thickness of a second nitride semiconductor portion is smaller than a thickness of the GaN substrate and a thickness of the third nitride semiconductor portion.

8. The semiconductor light emitting element according to claim 1, wherein the Al composition ratio of the second nitride semiconductor portion is the same as the Al composition ratio of the third nitride semiconductor portion.

9. The semiconductor light emitting element according to claim 1, further comprising an n-type semiconductor layer, an active layer, and a p-side semiconductor layer in this order on the third nitride semiconductor portion.

10. The semiconductor light emitting element according to claim 9, further comprising a crack inhibiting layer between the third nitride semiconductor portion and the n-type semiconductor layer.

11. The semiconductor light emitting element according to claim 1, wherein the GaN substrate contains Ge.

12. The semiconductor light emitting element according to claim 1, wherein
the n-type impurity of the first nitride semiconductor portion, the n-type impurity of the second nitride semiconductor portion, and the n-type impurity of the third nitride semiconductor portion are composed of the same element.
